(19) United States
(12) Patent Application Publication
(10) Pub. No.: US 2025/0203858 A1
(43) Pub. Date: Jun. 19, 2025

(54) MULTI-WRITE READ-ONLY MEMORY ARRAY AND READ-ONLY MEMORY THEREOF

(71) Applicant: YIELD MICROELECTRONICS CORP., HSIN-CHU COUNTY (TW)

(72) Inventors: YU-TING HUANG, HSIN-CHU COUNTY (TW); CHI-PEI WU, HSIN-CHU COUNTY (TW); LIEN-SING TSENG, HSIN-CHU COUNTY (TW)

(21) Appl. No.: 18/624,418

(22) Filed: Apr. 2, 2024

(30) Foreign Application Priority Data
Dec. 18, 2023 (TW) 112149187

(51) Int. Cl. H10B 20/00; G11C 17/12

(52) U.S. Cl. CPC H10B 20/387; G11C 17/126

(57) ABSTRACT

The disclosure describes a multi-write read-only memory array and a read-only memory thereof. The read-only memory array includes common-source lines, word bit lines, and sub-memory arrays. The common-source lines include a first common-source line and a second common-source line. The word bit lines include a first word bit line and a second word bit line. Each sub-memory array includes four memory cells. Each memory cell is coupled to the word bit line and the common-source line. The read-only memory includes a field-effect transistor and a capacitor. The source of the field-effect transistor is coupled to the word bit line. The drain of the field-effect transistor is coupled to the common-source line. The capacitor is coupled to the gate of the field-effect transistor and the word bit line.

### BACKGROUND OF THE INVENTION

This application claims priority for the TW patent application no. 112149187 filed on 18 Dec. 2023, the content of which is incorporated by reference in its entirely.

### FIELD OF THE INVENTION

The present invention relates to a memory device, particularly to a multi-write read-only memory array and a read-only memory thereof.

### DESCRIPTION OF THE RELATED ART

The Complementary Metal Oxide Semiconductor (CMOS) technology has been developed as a commonly used process for fabricating Application Specific Integrated Circuits (ASIC). Nowadays, as the computer information products are blooming, flash memories and Electrically Erasable Programmable Read Only Memory (EEPROM) have been widely used in electronic products since the data stored within will not volatilize but can be erased and programmed electrically. In addition, the data will not disappear even after the power is turned off.

Non-volatile memories are programmable and are able to adjust gate voltages of their transistors by storing charges, or to preserve the original gate voltages of transistors by not storing charges. When regarding to erase a non-volatile memory, the charges stored in the non-volatile memory are removed to resume the initial state of the memory, and return to its original gate voltages of the transistors. When the non-volatile memory is programmed, its internal switches will be turned off or turned on. In order to program the non-volatile memory array, a certain voltage and current need to be applied, so that the corresponding switches can be turned on or off. In order to improve the stability, reliability, power consumption, storage density and read speed of the read-only memory, the area of the gate capacitor is usually larger. However, when the area of the gate capacitor becomes larger, the overall resistance becomes higher and the capacitance becomes lower.

To overcome the abovementioned problems, the present invention provides a multi-write read-only memory array and a read-only memory thereof, so as to solve the afore-mentioned problems of the prior art.

### SUMMARY OF THE INVENTION

The present invention provides a multi-write read-only memory array and a read-only memory thereof, which greatly reduces the area of a capacitor and an overall resistance and increases capacitance.

In an embodiment of the present invention, a multi-write read-only memory array is provided. The multi-write read-only memory array includes a plurality of common-source lines, a plurality of word bit lines, and a plurality of sub-memory arrays. The common-source lines, arranged in parallel, include a first common-source line and a second common-source line. The word bit lines are arranged in parallel. The word bit lines perpendicular to the common-source lines include a first word bit line and a second word bit line. Each sub-memory array is coupled to two common-source lines and two word bit lines. Each sub-memory array includes a first memory cell, a second memory cell, a third memory cell, and a fourth memory cell. The control terminal of the first memory cell is coupled to the first word bit line. The data terminal of the first memory cell is coupled to the first common-source line and the first word bit line. The control terminal of the second memory cell is coupled to the second word bit line and the data terminal of the second memory cell is coupled to the first common-source line and the second word bit line. The control terminal of the third memory cell is coupled to the second word bit line and the data terminal of the third memory cell is coupled to the second common-source line and the second word bit line. The control terminal of the fourth memory cell is coupled to the first word bit line and the data terminal of the fourth memory cell is coupled to the second common-source line and the first word bit line.

In an embodiment of the present invention, the first memory cell and the second memory cell are symmetric about the first common-source line. The third memory cell and the fourth memory cell are symmetric about the second common-source line. The second memory cell and the third memory cell are located between the first memory cell and the fourth memory cell.

In an embodiment of the present invention, the first memory cell, the second memory cell, the third memory cell, and the fourth memory cell are formed in a semiconductor region having a first conductivity type. The first memory cell, the second memory cell, the third memory cell, and the fourth memory cell commonly include a first gate dielectric block, a second gate dielectric block, a third gate dielectric block, a fourth gate dielectric block, a first conductive gate, a second conductive gate, a third conductive gate, a fourth conductive gate, a first heavily-doped area, a second heavily-doped area, a third heavily-doped area, a fourth heavily-doped area, and a fifth heavily-doped area. The first gate dielectric block, the second gate dielectric block, the third gate dielectric block, and the fourth gate dielectric block are respectively formed on the semiconductor region. The first conductive gate, the second conductive gate, the third conductive gate, and the fourth conductive gate are respectively formed on the first gate dielectric block, the second gate dielectric block, the third gate dielectric block, and the fourth gate dielectric block. The first heavily-doped area and the second heavily-doped area are formed in the semiconductor region, respectively formed on two opposite side of the semiconductor region, which is directly arranged under the first conductive gate, and respectively coupled to the first word bit line and the first common-source line. The first heavily-doped area and the second heavily-doped area have a second conductivity type opposite to the first conductivity type. The third heavily-doped area is formed in the semiconductor region. The second heavily-doped area and the third heavily-doped area are respectively formed on two opposite side of the semiconductor region, which is directly arranged under the second conductive gate. The third heavily-doped area is coupled to the second word bit line. The third heavily-doped area has the second conductivity type. The fourth heavily-doped area is formed in the semiconductor region. The third heavily-doped area and the fourth heavily-doped area are respectively formed on two opposite side of the semiconductor region, which is directly arranged under the third conductive gate. The fourth heavily-doped area is coupled to the second common-source line. The fourth heavily-doped area has the second conductivity type. The fifth heavily-doped area is formed in the semiconductor region. The fourth heavily-doped area and the fifth heavily-doped area are respectively formed on two opposite side of the semiconductor region, which is directly arranged under the fourth conductive gate. The fifth heavily-doped area is coupled to the first word bit line. The fifth heavily-doped area has the second conductivity type.

In an embodiment of the present invention, the first conductivity type is a P type and the second conductivity type is an N type.

In an embodiment of the present invention, when the first memory cell is selected to perform a programming activity, the semiconductor region is coupled to a grounding voltage, the first word bit line is coupled to a middle voltage or a high voltage, and the first common-source line is coupled to the middle voltage or the grounding voltage. The high voltage is greater than the middle voltage and the middle voltage is greater than the grounding voltage.

In an embodiment of the present invention, when the first memory cell is not selected to perform a programming activity, the semiconductor region is coupled to a grounding voltage, the first word bit line is coupled to the grounding voltage, and the first common-source line is coupled to a low voltage or electrically floating. The low voltage is greater than the grounding voltage.

In an embodiment of the present invention, when the first memory cell is selected to perform an erasing activity, the semiconductor region is coupled to a grounding voltage, the first word bit line is coupled to the grounding voltage, and the first common-source line is coupled to a high voltage. The high voltage is greater than the grounding voltage.

In an embodiment of the present invention, when the first memory cell is not selected to perform an erasing activity, the semiconductor region is coupled to a grounding voltage, the first word bit line is electrically floating or coupled to a low voltage, and the first common-source line is electrically floating. The low voltage is greater than the grounding voltage.

In an embodiment of the present invention, when the first memory cell is selected to perform a reading activity, the first word bit line is coupled to a low voltage and the semiconductor region and the first common-source line are coupled to a grounding voltage. The low voltage is greater than the grounding voltage.

In an embodiment of the present invention, when the first memory cell is not selected to perform a reading activity, the semiconductor region and the first word bit line are coupled to a grounding voltage and the first common-source line is coupled to a low voltage or electrically floating. The low voltage is greater than the grounding voltage.

In an embodiment of the present invention, when the second memory cell is selected to perform a programming activity, the semiconductor region is coupled to a grounding voltage, the second word bit line is coupled to a middle voltage or a high voltage, and the first common-source line is coupled to the grounding voltage or the middle voltage. The high voltage is greater than the middle voltage and the middle voltage is greater than the grounding voltage.

In an embodiment of the present invention, when the second memory cell is not selected to perform a programming activity, the semiconductor region is coupled to a grounding voltage, the second word bit line is coupled to the grounding voltage, and the first common-source line is coupled to a low voltage or electrically floating. The low voltage is greater than the grounding voltage.

In an embodiment of the present invention, when the second memory cell is selected to perform an erasing activity, the semiconductor region is coupled to a grounding voltage, the second word bit line is coupled to the grounding voltage, and the first common-source line is coupled to a high voltage. The high voltage is greater than the grounding voltage.

In an embodiment of the present invention, when the second memory cell is not selected to perform an erasing activity, the semiconductor region is coupled to a grounding voltage, the second word bit line is electrically floating or coupled to a low voltage, and the first common-source line is electrically floating. The low voltage is greater than the grounding voltage.

In an embodiment of the present invention, when the second memory cell is selected to perform a reading activity, the second word bit line are coupled to a low voltage and the semiconductor region and the first common-source line is coupled to a grounding voltage. The low voltage is greater than the grounding voltage.

In an embodiment of the present invention, when the second memory cell is not selected to perform a reading activity, the semiconductor region and the second word bit line are coupled to a grounding voltage and the first common-source line is coupled to a low voltage or electrically floating. The low voltage is greater than the grounding voltage.

In an embodiment of the present invention, when the third memory cell is selected to perform a programming activity, the semiconductor region is coupled to a grounding voltage, the second word bit line is coupled to a middle voltage or a high voltage, and the second common-source line is coupled to the grounding voltage or the middle voltage. The high voltage is greater than the middle voltage and the middle voltage is greater than the grounding voltage.

In an embodiment of the present invention, when the third memory cell is not selected to perform a programming activity, the semiconductor region is coupled to a grounding voltage, the second word bit line is coupled to the grounding voltage, and the second common-source line is coupled to a low voltage or electrically floating. The low voltage is greater than the grounding voltage.

In an embodiment of the present invention, when the third memory cell is selected to perform an erasing activity, the semiconductor region is coupled to a grounding voltage, the second word bit line is coupled to the grounding voltage, and the second common-source line is coupled to a high voltage. The high voltage is greater than the grounding voltage.

In an embodiment of the present invention, when the third memory cell is not selected to perform an erasing activity, the semiconductor region is coupled to a grounding voltage, the second word bit line is electrically floating or coupled to a low voltage, and the second common-source line is electrically floating. The low voltage is greater than the grounding voltage.

In an embodiment of the present invention, when the third memory cell is selected to perform a reading activity, the second word bit line are coupled to a low voltage and the semiconductor region and the second common-source line is coupled to a grounding voltage. The low voltage is greater than the grounding voltage.

In an embodiment of the present invention, when the third memory cell is not selected to perform a reading activity, the semiconductor region and the second word bit line are coupled to a grounding voltage and the second common-source line is coupled to a low voltage or electrically floating. The low voltage is greater than the grounding voltage.

In an embodiment of the present invention, when the fourth memory cell is selected to perform a programming activity, the semiconductor region is coupled to a grounding voltage, the first word bit line is coupled to a middle voltage or a high voltage, and the second common-source line is coupled to the grounding voltage or the middle voltage. The high voltage is greater than the middle voltage and the middle voltage is greater than the grounding voltage.

In an embodiment of the present invention, when the fourth memory cell is not selected to perform a programming activity, the semiconductor region is coupled to a grounding voltage, the first word bit line is coupled to the grounding voltage, and the second common-source line is coupled to a low voltage or electrically floating. The low voltage is greater than the grounding voltage.

In an embodiment of the present invention, when the fourth memory cell is selected to perform an erasing activity, the semiconductor region is coupled to a grounding voltage, the first word bit line is coupled to the grounding voltage, and the second common-source line is coupled to a high voltage. The high voltage is greater than the grounding voltage.

In an embodiment of the present invention, when the fourth memory cell is not selected to perform an erasing activity, the semiconductor region is coupled to a grounding voltage, the first word bit line is electrically floating or coupled to a low voltage, and the second common-source line is electrically floating. The low voltage is greater than the grounding voltage.

In an embodiment of the present invention, when the fourth memory cell is selected to perform a reading activity, the first word bit line are coupled to a low voltage and the semiconductor region and the second common-source line is coupled to a grounding voltage. The low voltage is greater than the grounding voltage.

In an embodiment of the present invention, when the fourth memory cell is not selected to perform a reading activity, the semiconductor region and the first word bit line are coupled to a grounding voltage and the second common-source line is coupled to a low voltage or electrically floating. The low voltage is greater than the grounding voltage.

In an embodiment of the present invention, the first conductivity type is an N type and the second conductivity type is a P type.

In an embodiment of the present invention, when the first memory cell is selected to perform a programming activity, the semiconductor region is coupled to a high voltage, the first word bit line is coupled to a middle voltage or a grounding voltage, and the first common-source line is coupled to the middle voltage or the high voltage. The high voltage is greater than the middle voltage and the middle voltage is greater than the grounding voltage.

In an embodiment of the present invention, when the first memory cell is not selected to perform a programming activity, the semiconductor region is coupled to a high voltage, the first word bit line is coupled to the high voltage, and the first common-source line is coupled to a middle voltage or electrically floating. The high voltage is greater than the middle voltage.

In an embodiment of the present invention, when the first memory cell is selected to perform an erasing activity, the semiconductor region is coupled to a high voltage, the first word bit line is coupled to the high voltage, and the first common-source line is coupled to a grounding voltage. The high voltage is greater than the grounding voltage.

In an embodiment of the present invention, when the first memory cell is not selected to perform an erasing activity, the semiconductor region is coupled to a high voltage, the first word bit line is coupled to a middle voltage or electrically floating, and the first common-source line is electrically floating. The high voltage is greater than the middle voltage.

In an embodiment of the present invention, when the first memory cell is selected to perform a reading activity, the semiconductor region and the first common-source line are coupled to a middle voltage and the first word bit line is coupled to a low voltage. The middle voltage is greater than the low voltage.

In an embodiment of the present invention, when the first memory cell is not selected to perform a reading activity, the semiconductor region and the first word bit line are coupled to a middle voltage and the first common-source line is coupled to a low voltage or electrically floating. The middle voltage is greater than the low voltage.

In an embodiment of the present invention, when the second memory cell is selected to perform a programming activity, the semiconductor region is coupled to a high voltage, the second word bit line is coupled to a middle voltage or a grounding voltage, and the first common-source line is coupled to the middle voltage or the high voltage. The high voltage is greater than the middle voltage and the middle voltage is greater than the grounding voltage.

In an embodiment of the present invention, when the second memory cell is not selected to perform a programming activity, the semiconductor region is coupled to a high voltage, the second word bit line is coupled to the high voltage, and the first common-source line is coupled to a middle voltage or electrically floating. The high voltage is greater than the middle voltage.

In an embodiment of the present invention, when the second memory cell is selected to perform an erasing activity, the semiconductor region is coupled to a high voltage, the second word bit line is coupled to the high voltage, and the first common-source line is coupled to a grounding voltage. The high voltage is greater than the grounding voltage.

In an embodiment of the present invention, when the second memory cell is not selected to perform an erasing activity, the semiconductor region is coupled to a high voltage, the second word bit line is coupled to a middle voltage or electrically floating, and the first common-source line is electrically floating. The high voltage is greater than the middle voltage.

In an embodiment of the present invention, when the second memory cell is selected to perform a reading activity, the semiconductor region and the first common-source line are coupled to a middle voltage and the second word bit line is coupled to a low voltage. The middle voltage is greater than the low voltage.

In an embodiment of the present invention, when the second memory cell is not selected to perform a reading activity, the semiconductor region and the second word bit line are coupled to a middle voltage and the first common-source line is coupled to a low voltage or electrically floating. The middle voltage is greater than the low voltage.

In an embodiment of the present invention, when the third memory cell is selected to perform a programming activity, the semiconductor region is coupled to a high voltage, the second word bit line is coupled to a middle voltage or a grounding voltage, and the second common-source line is coupled to the middle voltage or the high voltage. The high voltage is greater than the middle voltage and the middle voltage is greater than the grounding voltage.

In an embodiment of the present invention, when the third memory cell is not selected to perform a programming activity, the semiconductor region is coupled to a high voltage, the second word bit line is coupled to the high voltage, and the second common-source line is coupled to a middle voltage or electrically floating. The high voltage is greater than the middle voltage.

In an embodiment of the present invention, when the third memory cell is selected to perform an erasing activity, the semiconductor region is coupled to a high voltage, the second word bit line is coupled to the high voltage, and the second common-source line is coupled to a grounding voltage. The high voltage is greater than the grounding voltage.

In an embodiment of the present invention, when the third memory cell is not selected to perform an erasing activity, the semiconductor region is coupled to a high voltage, the second word bit line is coupled to a middle voltage or electrically floating, and the second common-source line is electrically floating. The high voltage is greater than the middle voltage.

In an embodiment of the present invention, when the third memory cell is selected to perform a reading activity, the semiconductor region and the second common-source line are coupled to a middle voltage and the second word bit line is coupled to a low voltage. The middle voltage is greater than the low voltage.

In an embodiment of the present invention, when the third memory cell is not selected to perform a reading activity, the semiconductor region and the second word bit line are coupled to a middle voltage and the second common-source line is coupled to a low voltage or electrically floating. The middle voltage is greater than the low voltage.

In an embodiment of the present invention, when the fourth memory cell is selected to perform a programming activity, the semiconductor region is coupled to a high voltage, the first word bit line is coupled to a middle voltage or a grounding voltage, and the second common-source line is coupled to the middle voltage or the high voltage The high voltage is greater than the middle voltage and the middle voltage is greater than the grounding voltage.

In an embodiment of the present invention, when the fourth memory cell is not selected to perform a programming activity, the semiconductor region is coupled to a high voltage, the first word bit line is coupled to the high voltage, and the second common-source line is coupled to a middle voltage or electrically floating. The high voltage is greater than the middle voltage.

In an embodiment of the present invention, when the fourth memory cell is selected to perform an erasing activity, the semiconductor region is coupled to a high voltage, the first word bit line is coupled to the high voltage, and the second common-source line is coupled to a grounding voltage. The high voltage is greater than the grounding voltage.

In an embodiment of the present invention, when the fourth memory cell is not selected to perform an erasing activity, the semiconductor region is coupled to a high voltage, the first word bit line is coupled to a middle voltage or electrically floating, and the second common-source line is electrically floating. The high voltage is greater than the middle voltage.

In an embodiment of the present invention, when the fourth memory cell is selected to perform a reading activity, the semiconductor region and the second common-source line are coupled to a middle voltage and the first word bit line is coupled to a low voltage. The middle voltage is greater than the low voltage.

In an embodiment of the present invention, when the fourth memory cell is not selected to perform a reading activity, the semiconductor region and the first word bit line are coupled to a middle voltage and the second common-source line is coupled to a low voltage or electrically floating. The middle voltage is greater than the low voltage.

In an embodiment of the present invention, the semiconductor region is a semiconductor substrate or an epitaxial layer formed on a semiconductor substrate.

In an embodiment of the present invention, the first conductive gate has a first strip portion and first finger portions vertical to the first strip portion. One end of each of the first finger portions is connected to the first strip portion and another end of each of the first finger portions extends to the first heavily-doped area. The second conductive gate has a second strip portion and second finger portions vertical to the second strip portion. One end of each of the second finger portions is connected to the second strip portion and another end of each of the second finger portions extends to the third heavily-doped area. The third conductive gate has a third strip portion and third finger portions vertical to the third strip portion. One end of each of the third finger portions is connected to the third strip portion and another end of each of the third finger portions extends to the third heavily-doped area. The fourth conductive gate has a fourth strip portion and fourth finger portions vertical to the fourth strip portion. One end of each of the fourth finger portions is connected to the fourth strip portion and another end of each of the fourth finger portions extends to the fifth heavily-doped area.

In an embodiment of the present invention, a read-only memory includes a field-effect transistor and a capacitor. The source of the field-effect transistor is coupled to a word bit line and the drain of the field-effect transistor is coupled to a common-source line. The word bit line is perpendicular to the common-source line. One terminal of the capacitor is coupled to the gate of the field-effect transistor and another terminal of the capacitor is coupled to the word bit line.

In an embodiment of the present invention, the field-effect transistor and the capacitor are formed in a semiconductor region having a first conductivity type. The field-effect transistor and the capacitor commonly include a gate dielectric block, a conductive gate, a first heavily-doped area, and a second heavily-doped area. The gate dielectric block is formed on the semiconductor region. The conductive gate is formed on the gate dielectric block. The first heavily-doped area and the second heavily-doped area are formed in the semiconductor region, respectively formed on two opposite side of the semiconductor region, which is directly arranged under the conductive gate, and respectively coupled to the word bit line and the common-source line. The first heavily-doped area and the second heavily-doped area have a second conductivity type opposite to the first conductivity type.

In an embodiment of the present invention, the first conductivity type is a P type and the second conductivity type is an N type.

In an embodiment of the present invention, the first conductivity type is an N type and the second conductivity type is a P type.

In an embodiment of the present invention, the conductive gate has a strip portion and finger portions vertical to the strip portion. One end of each of the finger portions is connected to the strip portion and another end of each of the finger portions extends to the first heavily-doped area.

In an embodiment of the present invention, the semiconductor region is a semiconductor substrate or an epitaxial layer formed on a semiconductor substrate.

To sum up, the embodiments of the multi-write read-only memory array employs the source of a field-effect transistor to provide a gate voltage to greatly reduce the area of a capacitor.

Below, the embodiments are described in detail in cooperation with the drawings to make easily understood the technical contents, characteristics and accomplishments of the present invention.

### BRIEF DESCRIPTION OF THE DRAWINGS

FIG. 1 is a schematic diagram illustrating the circuit layout of a multi-write read-only memory array according to an embodiment of the present invention;

FIG. 2 is a schematic diagram illustrating the circuit layout of a sub-memory array according to an embodiment of the present invention;

FIG. 3 is a cross-sectional view of a first memory cell and a second memory cell according to an embodiment of the present invention;

FIG. 4 is a cross-sectional view of a third memory cell and a fourth memory cell according to an embodiment of the present invention;

FIG. 5 is a schematic diagram illustrating the equivalent circuit of a sub-memory array according to an embodiment of the present invention;

FIG. 6 is a schematic diagram illustrating the equivalent circuit of a sub-memory array according to another embodiment of the present invention;

FIG. 7 is a cross-sectional view of a first memory cell and a second memory cell according to another embodiment of the present invention;

FIG. 8 is a cross-sectional view of a third memory cell and a fourth memory cell according to another embodiment of the present invention; and

FIG. 9 is a schematic diagram illustrating the circuit layout of a sub-memory array according to another embodiment of the present invention;

FIG. 10 is a schematic diagram illustrating the equivalent circuit of a read-only memory according to an embodiment of the present invention;

FIG. 11 is a schematic diagram illustrating the equivalent circuit of a read-only memory according to another embodiment of the present invention;

FIG. 12 is a schematic diagram illustrating the circuit layout of a read-only memory according to an embodiment of the present invention;

FIG. 13 is a cross-sectional view of a read-only memory according to an embodiment of the present invention;

FIG. 14 is a cross-sectional view of a read-only memory according to another embodiment of the present invention; and

FIG. 15 is a schematic diagram illustrating the circuit layout of a read-only memory according to another embodiment of the present invention.

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Unless otherwise specified, some conditional sentences or words, such as “can”, “could”, “might”, or “may”, usually attempt to express what the embodiment in the present invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment.

Certain terms are used throughout the description and the claims to refer to particular components. One skilled in the art appreciates that a component may be referred to using different names. This disclosure does not intend to distinguish between components that differ in name but in function. In the description and in the claims, the term “comprise” is used in an open-ended fashion, and thus should be interpreted to mean “include, but not limited to.” The phrases “be coupled to,” “couples to,” and “coupling to” are intended to encompass any indirect or direct connection. Accordingly, if this disclosure mentions that a first device is coupled with a second device, it means that the first device may be directly or indirectly connected to the second device through electrical connections, wireless communications, optical communications, or other signal connections with/without other intermediate devices or connection means.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the articles “a” and “the” includes the meaning of “one or at least one” of the elements or components. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. The examples in the present specification do not limit the claimed scope of the invention.

In the following description, a multi-write read-only memory array and a read-only memory thereof will be provided, which employs the source of a field-effect transistor to provide a gate voltage to greatly reduce the area of a capacitor and an overall resistance and increases capacitance.

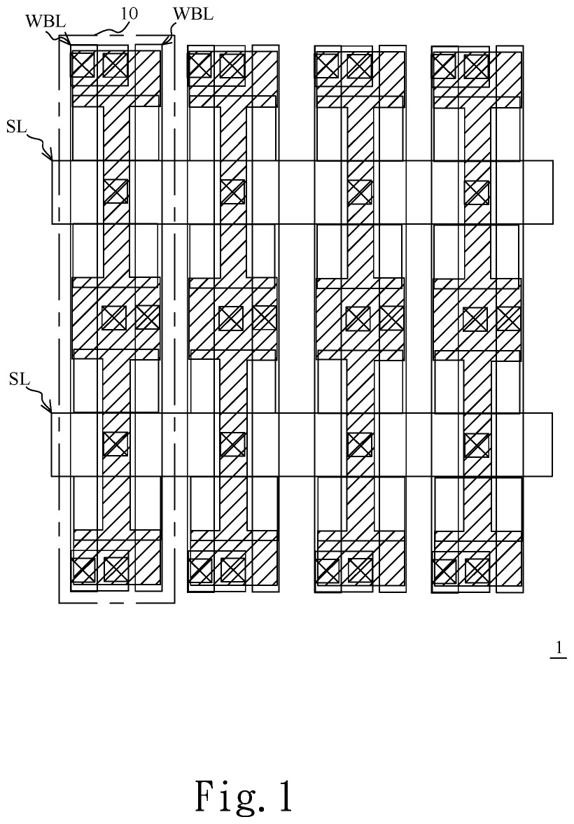

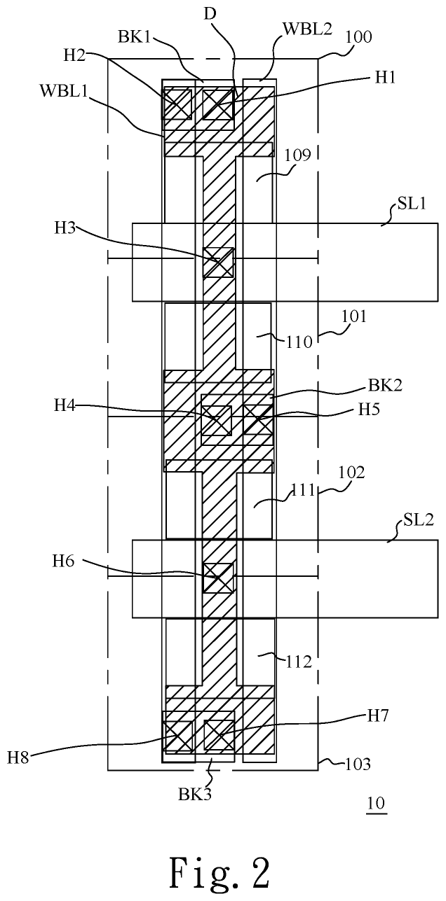

FIG. 1 is a schematic diagram illustrating the circuit layout of a multi-write read-only memory array according to an embodiment of the present invention. FIG. 2 is a schematic diagram illustrating the circuit layout of a sub-memory array according to an embodiment of the present invention. Referring to FIG. 1 and FIG. 2, a multi-write read-only memory array 1 of the present invention is introduced as follows. The multi-write read-only memory array 1 includes a plurality of common-source lines SL arranged in parallel, a plurality of word bit lines WBL arranged in parallel, and a plurality of sub-memory arrays 10. The common-source lines SL include a first common-source line SL1 and a second common-source line SL2. The word bit lines WBL are perpendicular to the common-source lines SL. The common-source lines SL are a part of a first conduction metal layer. The word bit lines WBL are a part of a second conduction metal layer. The word bit lines WBL include a first word bit line WBL1 and a second word bit line WBL2. Each sub-memory array 10 is coupled to two of the common-source lines SL and two of the word bit lines WBL. Each sub-memory array 10 includes a first memory cell 100, a second memory cell 101, a third memory cell 102, and a fourth memory cell 103. The control terminal of the first memory cell 100 is coupled to the first word bit line WBL1. The data terminal of the first memory cell 100 is coupled to the first common-source line SL1 and the first word bit line WBL1. The control terminal of the second memory cell 101 is coupled to the second word bit line WBL2. The data terminal of the second memory cell 101 is coupled to the first common-source line SL1 and the second word bit line WBL2. The control terminal of the third memory cell 102 is coupled to the second word bit line WBL2. The data terminal of the third memory cell 102 is coupled to the second common-source line SL2 and the second word bit line WBL2. The control terminal of the fourth memory cell 103 is coupled to the first word bit line WBL1. The data terminal of the fourth memory cell 103 is coupled to the second common-source line SL2 and the first word bit line WBL1. In some embodiments of the present invention, the first memory cell 100 and the second memory cell 101 are symmetric about the first common-source line SL1, the third memory cell 102 and the fourth memory cell 103 are symmetric about the second common-source line SL2, and the second memory cell 101 and the third memory cell 102 are located between the first memory cell 100 and the fourth memory cell 103.

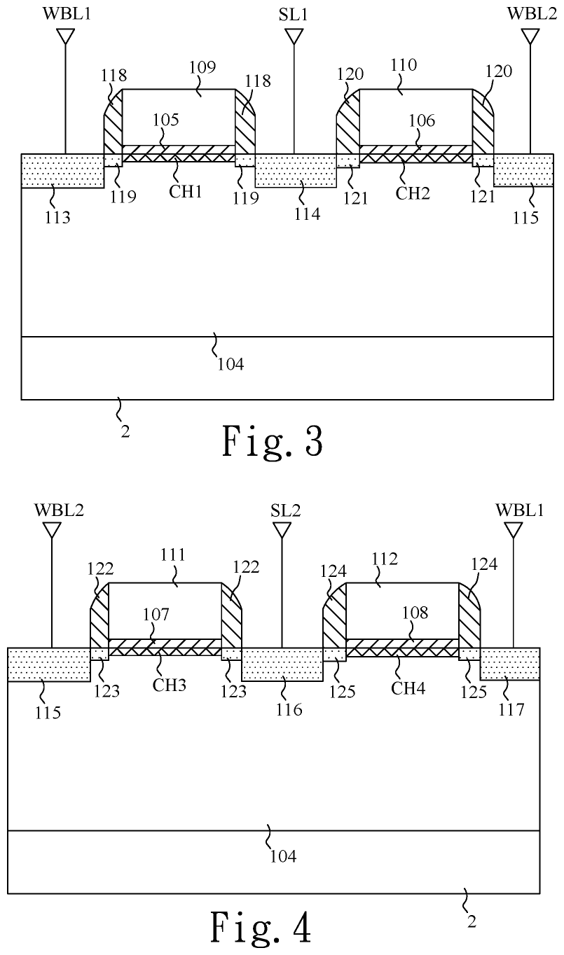

FIG. 3 is a cross-sectional view of a first memory cell and a second memory cell according to an embodiment of the present invention. FIG. 4 is a cross-sectional view of a third memory cell and a fourth memory cell according to an embodiment of the present invention. Referring to FIG. 2, FIG. 3, and FIG. 4, the first memory cell 100, the second memory cell 101, the third memory cell 102, and the fourth memory cell 103 are formed in a semiconductor region 104 having a first conductivity type. The semiconductor region 104 may be a semiconductor substrate or an epitaxial layer formed on a semiconductor substrate. In the embodiment, the semiconductor region 104 is exemplified by an epitaxial layer formed on a semiconductor substrate 2. The first memory cell 100, the second memory cell 101, the third memory cell 102, and the fourth memory cell 103 commonly include a first gate dielectric block 105, a second gate dielectric block 106, a third gate dielectric block 107, a fourth gate dielectric block 108, a first conductive gate 109, a second conductive gate 110, a third conductive gate 111, a fourth conductive gate 112, a first heavily-doped area 113, a second heavily-doped area 114, a third heavily-doped area 115, a fourth heavily-doped area 116, and a fifth heavily-doped area 117. The first gate dielectric block 105, the second gate dielectric block 106, the third gate dielectric block 107, and the fourth gate dielectric block 108 are a part of a dielectric layer D. The first conductive gate 109, the second conductive gate 110, the third conductive gate 111, and the fourth conductive gate 112 are a part of an electrode layer. The first gate dielectric block 105, the second gate dielectric block 106, the third gate dielectric block 107, and the fourth gate dielectric block 108 are respectively formed on the semiconductor region 104. The first conductive gate 109, the second conductive gate 110, the third conductive gate 111, and the fourth conductive gate 112 are respectively formed on the first gate dielectric block 105, the second gate dielectric block 106, the third gate dielectric block 107, and the fourth gate dielectric block 108. The first heavily-doped area 113 and the second heavily-doped area 114 are formed in the semiconductor region 104, respectively formed on two opposite side of the semiconductor region 104, which is directly arranged under the first conductive gate 109, and respectively coupled to the first word bit line WBL1 and the first common-source line SL1. The first heavily-doped area 113 and the second heavily-doped area 114 have a second conductivity type opposite to the first conductivity type. In the embodiment, the first conductivity type is a P-type and the second conductivity type is an N type. A first conduction metal block BK1, a second conduction metal block BK2, and a third conduction metal block BK3 are a part of the first conduction metal layer. The electrode layer, the first conduction metal layer, and the second conduction metal layer are sequentially arranged from bottom to top. The third heavily-doped area 115 is formed in the semiconductor region 104. The second heavily-doped area 114 and the third heavily-doped area 115 are respectively formed on two opposite side of the semiconductor region 104, which is directly arranged under the second conductive gate 110. The third heavily-doped area 115 is coupled to the second word bit line WBL2. The third heavily-doped area 115 has the second conductivity type. The fourth heavily-doped area 116 is formed in the semiconductor region 104. The third heavily-doped area 115 and the fourth heavily-doped area 116 are respectively formed on two opposite side of the semiconductor region 104, which is directly arranged under the third conductive gate 111. The fourth heavily-doped area 116 is coupled to the second common-source line SL2. The fourth heavily-doped area 116 has the second conductivity type. The fifth heavily-doped area 117 is formed in the semiconductor region 104. The fourth heavily-doped area 116 and the fifth heavily-doped area 117 are respectively formed on two opposite side of the semiconductor region 104, which is directly arranged under the fourth conductive gate 112. The fifth heavily-doped area 117 is coupled to the first word bit line WBL1. The fifth heavily-doped area 117 has the second conductivity type.

The first word bit line WBL1 overlaps a second conduction via H2. The second conduction via H2 and a first conduction via H1 overlap the first conduction block BKL. The first conduction via H1 penetrates through the dielectric layer D. The first heavily-doped area 113 is coupled to the first word bit line WBL1 through the first conduction via H1, the first conduction block BK1, and the second conduction via H2 in sequence. The first common-source line SL1 overlaps a third conduction via H3. The third conduction via H3 penetrates through the dielectric layer D. The second heavily-doped area 114 is coupled to the first common-source SL1 through the third conduction via H3. Since the third conduction via H3 only provides voltage for the first common-source SL1 rather than connects to other components, the overall resistance of each sub-memory array 10 can be reduced. A fourth conduction via H4 penetrates through the dielectric layer D. The fourth conduction via H4 and a fifth conduction via H5 overlap the second conduction block BK2. The third heavily-doped area 115 is coupled to the second word bit line WBL2 through the fourth conduction via H4, the second conduction block BK2, and the fifth conduction via H5. The second common-source line SL2 overlaps a sixth conduction via H6. The sixth conduction via H6 penetrates through the dielectric layer D. The fourth heavily-doped area 116 is coupled to the second common-source line SL2 through the sixth conduction via H6. Since the sixth conduction via H6 only provides voltage for the second common-source line SL2 rather than connects to other components, the overall resistance of each sub-memory array 10 can be reduced. The first word bit line WBL1 overlaps an eighth conduction via H8. A seventh conduction via H7 and the eighth conduction via H8 overlap a third conduction metal BK3. The seventh conduction via H7 penetrates through the dielectric layer D. The fifth heavily-doped area 117 is coupled to the first word bit line WBL1 through the seventh conduction via H7, the third conduction metal BK3, and the eighth conduction via H8.

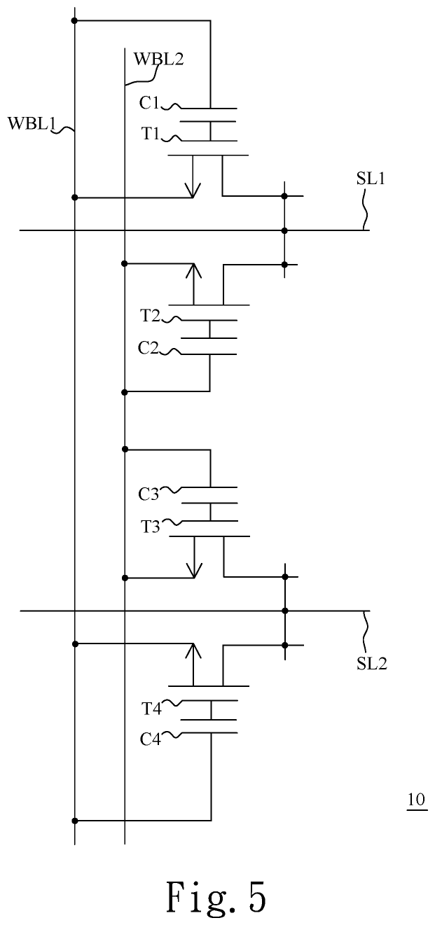

FIG. 5 is a schematic diagram illustrating the equivalent circuit of a sub-memory array according to an embodiment of the present invention. Please refer to FIG. 3, FIG. 4, and FIG. 5. The first heavily-doped area 113, the second heavily-doped area 114, the first gate dielectric block 105, the semiconductor region 104, and the first conductive gate 109 form a first metal-oxide-semiconductor field-effect transistor (MOSFET) T1. The first conductive gate 109 and the first heavily-doped area 113 form a first capacitor C1. The first heavily-doped area 113 is used as a source and the second heavily-doped area 114 is used as a drain. The two sidewalls of the first conductive gate 109 are respectively provided with two first sidewall spacers 118 that extend to the sidewall of the first gate dielectric block 105. There are two first lightly-doped drains (LDDs) 119 which are directly respectively formed under the two first sidewall spacers 118. When the first MOSFET T1 is turned on, a channel region CH1 is formed between the first LDDs 119.

The third heavily-doped area 115, the second heavily-doped area 114, the second gate dielectric block 106, the semiconductor region 104, and the second conductive gate 110 form a second metal-oxide-semiconductor field-effect transistor (MOSFET) T2. The second conductive gate 110 and the third heavily-doped area 115 form a second capacitor C2. The third heavily-doped area 115 is used as a source and the second heavily-doped area 114 is used as a drain. The two sidewalls of the second conductive gate 110 are respectively provided with two second sidewall spacers 120 that extend to the sidewall of the second gate dielectric block 106. There are two second lightly-doped drains (LDDs) 121 which are directly respectively formed under the two second sidewall spacers 120. When the second MOSFET T2 is turned on, a channel region CH2 is formed between the second LDDs 121.

The third heavily-doped area 115, the fourth heavily-doped area 116, the third gate dielectric block 107, the semiconductor region 104, and the third conductive gate 111 form a third metal-oxide-semiconductor field-effect transistor (MOSFET) T3. The third conductive gate 111 and the third heavily-doped area 115 form a third capacitor C3. The third heavily-doped area 115 is used as a source and the fourth heavily-doped area 116 is used as a drain. The two sidewalls of the third conductive gate 111 are respectively provided with two third sidewall spacers 122 that extend to the sidewall of the third gate dielectric block 107. There are two third lightly-doped drains (LDDs) 123 which are directly respectively formed under the two third sidewall spacers 122. When the third MOSFET T3 is turned on, a channel region CH3 is formed between the third LDDs 123.

The fifth heavily-doped area 117, the fourth heavily-doped area 116, the fourth gate dielectric block 108, the semiconductor region 104, and the fourth conductive gate 112 form a fourth metal-oxide-semiconductor field-effect transistor (MOSFET) T4. The fourth conductive gate 112 and the fifth heavily-doped area 117 form a fourth capacitor C4. The fifth heavily-doped area 117 is used as a source and the fourth heavily-doped area 116 is used as a drain. The two sidewalls of the fourth conductive gate 112 are respectively provided with two fourth sidewall spacers 124 that extend to the sidewall of the fourth gate dielectric block 108. There are two fourth lightly-doped drains (LDDs) 125 which are directly respectively formed under the two fourth sidewall spacers 124. When the fourth MOSFET T4 is turned on, a channel region CH4 is formed between the fourth LDDs 125.

The operation of the first memory cell 100 is introduced as follows, including those of programming, erasing, and reading activities. The common-source line or the word bit line is electrically floating or coupled to a high voltage, a middle voltage, or a grounding voltage based on the process characteristics.

When the first memory cell 100 is selected to perform a programming activity, the semiconductor region 104 is coupled to a grounding voltage, the first word bit line WBL1 is coupled to a middle voltage or a high voltage, and the first common-source line SL1 is coupled to the middle voltage or the grounding voltage. When the first memory cell 100 is not selected to perform a programming activity, the semiconductor region 104 is coupled to the grounding voltage, the first word bit line WBL1 is coupled to the grounding voltage, and the first common-source line SL1 is coupled to the low voltage or electrically floating. When the first memory cell 100 is selected to perform an erasing activity, the semiconductor region 104 is coupled to the grounding voltage, the first word bit line WBL1 is coupled to the grounding voltage, and the first common-source line SL1 is coupled to the high voltage. When the first memory cell 100 is not selected to perform an erasing activity, the semiconductor region 104 is coupled to the grounding voltage, the first word bit line WBL1 is electrically floating or coupled to the low voltage, and the first common-source SL1 is electrically floating. When the first memory cell 100 is selected to perform a reading activity, the semiconductor region 104 and the first common-source line SL1 are coupled to the grounding voltage and the first word bit source line WBL1 is coupled to the low voltage. When the first memory cell 100 is not selected to perform a reading activity, the semiconductor region 104 and the first word bit line WBL1 are coupled to the grounding voltage and the first common-source line SL1 is coupled to the low voltage or electrically floating. In the foregoing operation, the high voltage is greater than the middle voltage, the middle voltage is greater than the low voltage, and the low voltage is greater than the grounding voltage. Specifically, the high voltage is slightly lower than the drain-to-source breakdown voltage of the first MOSFET T1. That is to say, the high voltage is equal to the drain-to-source breakdown voltage of the first MOSFET T1 minus the threshold voltage of the first MOSFET T1. The middle voltage is equal to the drain-to-source breakdown voltage of the first MOSFET T1×0.5. The low voltage is equal to the drain-to-source breakdown voltage of the first MOSFET T1×0.25. The grounding voltage is zero voltage. Based on the foregoing operation, the first memory cell 100 employs the source of the first MOSFET T1 to provide a gate voltage, thereby greatly reducing the area of a capacitor.

The operation of the second memory cell 101 is introduced as follows, including those of programming, erasing, and reading activities. The common-source line or the word bit line is electrically floating or coupled to a high voltage, a middle voltage, or a grounding voltage based on the process characteristics.

When the second memory cell 101 is selected to perform a programming activity, the semiconductor region 104 is coupled to a grounding voltage, the second word bit line WBL2 is coupled to a middle voltage or a high voltage, and the first common-source line SL1 is coupled to the middle voltage or the grounding voltage. When the second memory cell 101 is not selected to perform a programming activity, the semiconductor region 104 is coupled to the grounding voltage, the second word bit line WBL2 is coupled to the grounding voltage, and the first common-source line SL1 is coupled to the low voltage or electrically floating. When the second memory cell 101 is selected to perform an erasing activity, the semiconductor region 104 is coupled to the grounding voltage, the second word bit line WBL2 is coupled to the grounding voltage, and the first common-source line SL1 is coupled to the high voltage. When the second memory cell 101 is not selected to perform an erasing activity, the semiconductor region 104 is coupled to the grounding voltage, the second word bit line WBL2 is electrically floating or coupled to the low voltage, and the first common-source SL1 is electrically floating. When the second memory cell 101 is selected to perform a reading activity, the semiconductor region 104 and the first common-source line SL1 are coupled to the grounding voltage and the second word bit line WBL2 is coupled to the low voltage. When the second memory cell 101 is not selected to perform a reading activity, the semiconductor region 104 and the second word bit line WBL2 are coupled to the grounding voltage and the first common-source line SL1 is coupled to the low voltage or electrically floating. In the foregoing operation, the high voltage is greater than the middle voltage, the middle voltage is greater than the low voltage, and the low voltage is greater than the grounding voltage. Specifically, the high voltage is slightly lower than the drain-to-source breakdown voltage of the second MOSFET T2. That is to say, the high voltage is equal to the drain-to-source breakdown voltage of the second MOSFET T2 minus the threshold voltage of the second MOSFET T2. The middle voltage is equal to the drain-to-source breakdown voltage of the second MOSFET T2×0.5. The low voltage is equal to the drain-to-source breakdown voltage of the second MOSFET T2×0.25. The grounding voltage is zero voltage. Based on the foregoing operation, the second memory cell 101 employs the source of the second MOSFET T2 to provide a gate voltage, thereby greatly reducing the area of a capacitor.

The operation of the third memory cell 102 is introduced as follows, including those of programming, erasing, and reading activities. The common-source line or the word bit line is electrically floating or coupled to a high voltage, a middle voltage, or a grounding voltage based on the process characteristics.

When the third memory cell 102 is selected to perform a programming activity, the semiconductor region 104 is coupled to a grounding voltage, the second word bit line WBL2 is coupled to a middle voltage or a high voltage, and the second common-source line SL2 is coupled to the middle voltage or the grounding voltage. When the third memory cell 102 is not selected to perform a programming activity, the semiconductor region 104 is coupled to the grounding voltage, the second word bit line WBL2 is coupled to the grounding voltage, and the second common-source line SL2 is coupled to the low voltage or electrically floating. When the third memory cell 102 is selected to perform an erasing activity, the semiconductor region 104 is coupled to the grounding voltage, the second word bit line WBL2 is coupled to the grounding voltage, and the second common-source line SL2 is coupled to the high voltage. When the third memory cell 102 is not selected to perform an erasing activity, the semiconductor region 104 is coupled to the grounding voltage, the second word bit line WBL2 is electrically floating or coupled to the low voltage, and the second common-source SL2 is electrically floating. When the third memory cell 102 is selected to perform a reading activity, the semiconductor region 104 and the second common-source line SL2 are coupled to the grounding voltage and the second word bit line WBL2 is coupled to the low voltage. When the third memory cell 102 is not selected to perform a reading activity, the semiconductor region 104 and the second word bit line WBL2 are coupled to the grounding voltage and the second common-source line SL2 is coupled to the low voltage or electrically floating. In the foregoing operation, the high voltage is greater than the middle voltage, the middle voltage is greater than the low voltage, and the low voltage is greater than the grounding voltage. Specifically, the high voltage is slightly lower than the drain-to-source breakdown voltage of the third MOSFET T3. That is to say, the high voltage is equal to the drain-to-source breakdown voltage of the third MOSFET T3 minus the threshold voltage of the third MOSFET T3. The middle voltage is equal to the drain-to-source breakdown voltage of the third MOSFET T3×0.5. The low voltage is equal to the drain-to-source breakdown voltage of the third MOSFET T3×0.25. The grounding voltage is zero voltage. Based on the foregoing operation, the third memory cell 102 employs the source of the third MOSFET T3 to provide a gate voltage, thereby greatly reducing the area of a capacitor.

The operation of the fourth memory cell 103 is introduced as follows, including those of programming, erasing, and reading activities. The common-source line or the word bit line is electrically floating or coupled to a high voltage, a middle voltage, or a grounding voltage based on the process characteristics.

When the fourth memory cell 103 is selected to perform a programming activity, the semiconductor region 104 is coupled to a grounding voltage, the first word bit line WBL1 is coupled to a middle voltage or a high voltage, and the second common-source line SL2 is coupled to the middle voltage or the grounding voltage. When the fourth memory cell 103 is not selected to perform a programming activity, the semiconductor region 104 is coupled to the grounding voltage, the first word bit line WBL1 is coupled to the grounding voltage, and the second common-source line SL2 is coupled to a low voltage or electrically floating. When the fourth memory cell 103 is selected to perform an erasing activity, the semiconductor region 104 is coupled to the grounding voltage, the first word bit line WBL1 is coupled to the grounding voltage, and the second common-source line SL2 is coupled to the high voltage. When the fourth memory cell 103 is not selected to perform an erasing activity, the semiconductor region 104 is coupled to the grounding voltage, the first word bit line WBL1 is electrically floating or coupled to the low voltage, and the second common-source SL2 is electrically floating. When the fourth memory cell 103 is selected to perform a reading activity, the semiconductor region 104 and the second common-source line SL2 are coupled to the grounding voltage and the first word bit line WBL1 is coupled to the low voltage. When the fourth memory cell 103 is not selected to perform a reading activity, the semiconductor region 104 and the first word bit line WBL1 are coupled to the grounding voltage and the second common-source line SL2 is coupled to the low voltage or electrically floating. In the foregoing operation, the high voltage is greater than the middle voltage, the middle voltage is greater than the low voltage, and the low voltage is greater than the grounding voltage. Specifically, the high voltage is slightly lower than the drain-to-source breakdown voltage of the fourth MOSFET T4. That is to say, the high voltage is equal to the drain-to-source breakdown voltage of the fourth MOSFET T4 minus the threshold voltage of the fourth MOSFET T4. The middle voltage is equal to the drain-to-source breakdown voltage of the fourth MOSFET T4×0.5. The low voltage is equal to the drain-to-source breakdown voltage of the fourth MOSFET T4×0.25. The grounding voltage is zero voltage. Based on the foregoing operation, the fourth memory cell 103 employs the source of the fourth MOSFET T4 to provide a gate voltage, thereby greatly reducing the area of a capacitor.

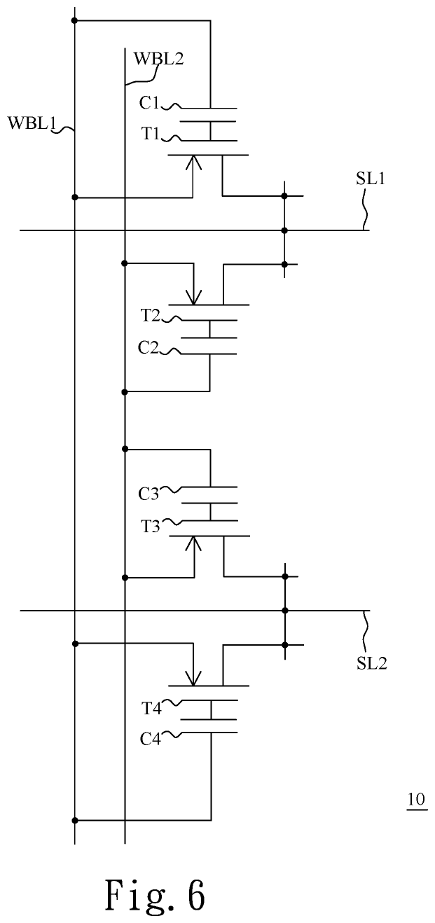

FIG. 6 is a schematic diagram illustrating the equivalent circuit of a sub-memory array according to another embodiment of the present invention. Please refer to FIG. 3, FIG. 4, and FIG. 6. In the embodiment, the first conductivity type is an N type and the second conductivity type is a P type. The operation of the first memory cell 100 is introduced as follows, including those of programming, erasing, and reading activities. The common-source line or the word bit line is electrically floating or coupled to a high voltage, a middle voltage, or a grounding voltage based on the process characteristics.

When the first memory cell 100 is selected to perform a programming activity, the semiconductor region 104 is coupled to a high voltage, the first word bit line WBL1 is coupled to a middle voltage or a grounding voltage, and the first common-source line SL1 is coupled to the middle voltage or the high voltage. When the first memory cell 100 is not selected to perform a programming activity, the semiconductor region 104 is coupled to the high voltage, the first word bit line WBL1 is coupled to the high voltage, and the first common-source line SL1 is coupled to the middle voltage or electrically floating. When the first memory cell 100 is selected to perform an erasing activity, the semiconductor region 104 is coupled to the high voltage, the first word bit line WBL1 is coupled to the high voltage, and the first common-source line SL1 is coupled to the grounding voltage. When the first memory cell 100 is not selected to perform an erasing activity, the semiconductor region 104 is coupled to the high voltage, the first word bit line WBL1 is coupled to the middle voltage or electrically floating, and the first common-source SL1 is electrically floating. When the first memory cell 100 is selected to perform a reading activity, the semiconductor region 104 and the first common-source line SL1 are coupled to the middle voltage and the first word bit line WBL1 is coupled to the low voltage. When the first memory cell 100 is not selected to perform a reading activity, the semiconductor region 104 and the first word bit line WBL1 are coupled to the middle voltage and the first common-source line SL1 is coupled to the low voltage or electrically floating. In the foregoing operation, the high voltage is greater than the middle voltage, the middle voltage is greater than the low voltage, and the low voltage is greater than the grounding voltage. Specifically, the high voltage is slightly lower than the source-to-drain breakdown voltage of the first MOSFET T1. That is to say, the high voltage is equal to the source-to-drain breakdown voltage of the first MOSFET T1 plus the threshold voltage of the first MOSFET T1. The middle voltage is equal to the source-to-drain breakdown voltage of the first MOSFET T1×0.5. The low voltage is equal to the source-to-drain breakdown voltage of the first MOSFET T1×0.25. The grounding voltage is zero voltage. Based on the foregoing operation, the first memory cell 100 employs the source of the first MOSFET T1 to provide a gate voltage, thereby greatly reducing the area of a capacitor.

The operation of the second memory cell 101 is introduced as follows, including those of programming, erasing, and reading activities. The common-source line or the word bit line is electrically floating or coupled to a high voltage, a middle voltage, or a grounding voltage based on the process characteristics.

When the second memory cell 101 is selected to perform a programming activity, the semiconductor region 104 is coupled to a high voltage, the second word bit line WBL2 is coupled to a middle voltage or a grounding voltage, and the first common-source line SL1 is coupled to the middle voltage or the high voltage. When the second memory cell 101 is not selected to perform a programming activity, the semiconductor region 104 is coupled to the high voltage, the second word bit line WBL2 is coupled to the high voltage, and the first common-source line SL1 is coupled to the middle voltage or electrically floating. When the second memory cell 101 is selected to perform an erasing activity, the semiconductor region 104 is coupled to the high voltage, the second word bit line WBL2 is coupled to the high voltage, and the first common-source line SL1 is coupled to the grounding voltage. When the second memory cell 101 is not selected to perform an erasing activity, the semiconductor region 104 is coupled to the high voltage, the second word bit line WBL2 is coupled to the middle voltage or electrically floating, and the first common-source SL1 is electrically floating. When the second memory cell 101 is selected to perform a reading activity, the semiconductor region 104 and the first common-source line SL1 are coupled to the middle voltage and the second word bit line WBL2 is coupled to the low voltage. When the second memory cell 101 is not selected to perform a reading activity, the semiconductor region 104 and the second word bit line WBL2 are coupled to the middle voltage and the first common-source line SL1 is coupled to the low voltage or electrically floating. In the foregoing operation, the high voltage is greater than the middle voltage, the middle voltage is greater than the low voltage, and the low voltage is greater than the grounding voltage. Specifically, the high voltage is slightly lower than the source-to-drain breakdown voltage of the second MOSFET T2. That is to say, the high voltage is equal to the source-to-drain breakdown voltage of the second MOSFET T2 plus the threshold voltage of the second MOSFET T2. The middle voltage is equal to the source-to-drain breakdown voltage of the second MOSFET T2×0.5. The low voltage is equal to the source-to-drain breakdown voltage of the second MOSFET T2×0.25. The grounding voltage is zero voltage. Based on the foregoing operation, the second memory cell 101 employs the source of the second MOSFET T2 to provide a gate voltage, thereby greatly reducing the area of a capacitor.

The operation of the third memory cell 102 is introduced as follows, including those of programming, erasing, and reading activities. The common-source line or the word bit line is electrically floating or coupled to a high voltage, a middle voltage, or a grounding voltage based on the process characteristics.

When the third memory cell 102 is selected to perform a programming activity, the semiconductor region 104 is coupled to a high voltage, the second word bit line WBL2 is coupled to a middle voltage or a grounding voltage, and the second common-source line SL2 is coupled to the middle voltage or the high voltage. When the third memory cell 102 is not selected to perform a programming activity, the semiconductor region 104 is coupled to the high voltage, the second word bit line WBL2 is coupled to the high voltage, and the second common-source line SL2 is coupled to the middle voltage or electrically floating. When the third memory cell 102 is selected to perform an erasing activity, the semiconductor region 104 is coupled to the high voltage, the second word bit line WBL2 is coupled to the high voltage, and the second common-source line SL2 is coupled to the grounding voltage. When the third memory cell 102 is not selected to perform an erasing activity, the semiconductor region 104 is coupled to the high voltage, the second word bit line WBL2 is coupled to the middle voltage or electrically floating, and the second common-source SL2 is electrically floating. When the third memory cell 102 is selected to perform a reading activity, the semiconductor region 104 and the second common-source line SL2 are coupled to the middle voltage and the second word bit line WBL2 is coupled to the low voltage. When the third memory cell 102 is not selected to perform a reading activity, the semiconductor region 104 and the second word bit line WBL2 are coupled to the middle voltage and the second common-source line SL2 is coupled to the low voltage or electrically floating. In the foregoing operation, the high voltage is greater than the middle voltage, the middle voltage is greater than the low voltage, and the low voltage is greater than the grounding voltage. Specifically, the high voltage is slightly lower than the source-to-drain breakdown voltage of the third MOSFET T3. That is to say, the high voltage is equal to the source-to-drain breakdown voltage of the third MOSFET T3 plus the threshold voltage of the third MOSFET T3. The middle voltage is equal to the source-to-drain breakdown voltage of the third MOSFET T3×0.5. The low voltage is equal to the source-to-drain breakdown voltage of the third MOSFET T3×0.25. The grounding voltage is zero voltage. Based on the foregoing operation, the third memory cell 102 employs the source of the third MOSFET T3 to provide a gate voltage, thereby greatly reducing the area of a capacitor.

The operation of the fourth memory cell 103 is introduced as follows, including those of programming, erasing, and reading activities. The common-source line or the word bit line is electrically floating or coupled to a high voltage, a middle voltage, or a grounding voltage based on the process characteristics.

When the fourth memory cell 103 is selected to perform a programming activity, the semiconductor region 104 is coupled to a high voltage, the first word bit line WBL1 is coupled to a middle voltage or a grounding voltage, and the second common-source line SL2 is coupled to the middle voltage or the high voltage. When the fourth memory cell 103 is not selected to perform a programming activity, the semiconductor region 104 is coupled to the high voltage, the first word bit line WBL1 is coupled to the high voltage, and the second common-source line SL2 is coupled to the middle voltage or electrically floating. When the fourth memory cell 103 is selected to perform an erasing activity, the semiconductor region 104 is coupled to the high voltage, the first word bit line WBL1 is coupled to the high voltage, and the second common-source line SL2 is coupled to the grounding voltage. When the fourth memory cell 103 is not selected to perform an erasing activity, the semiconductor region 104 is coupled to the high voltage, the first word bit line WBL1 is coupled to the middle voltage or electrically floating, and the second common-source SL2 is electrically floating. When the fourth memory cell 103 is selected to perform a reading activity, the semiconductor region 104 and the second common-source line SL2 are coupled to the middle voltage and the first word bit line WBL1 is coupled to the low voltage. When the fourth memory cell 103 is not selected to perform a reading activity, the semiconductor region 104 and the first word bit line WBL1 are coupled to the middle voltage and the second common-source line SL2 is coupled to the low voltage or electrically floating. In the foregoing operation, the high voltage is greater than the middle voltage, the middle voltage is greater than the low voltage, and the low voltage is greater than the grounding voltage. Specifically, the high voltage is slightly lower than the source-to-drain breakdown voltage of the fourth MOSFET T4. That is to say, the high voltage is equal to the source-to-drain breakdown voltage of the fourth MOSFET T4 plus the threshold voltage of the fourth MOSFET T4. The middle voltage is equal to the source-to-drain breakdown voltage of the fourth MOSFET T4×0.5. The low voltage is equal to the source-to-drain breakdown voltage of the fourth MOSFET T4×0.25. The grounding voltage is zero voltage. Based on the foregoing operation, the fourth memory cell 103 employs the source of the fourth MOSFET T4 to provide a gate voltage, thereby greatly reducing the area of a capacitor.

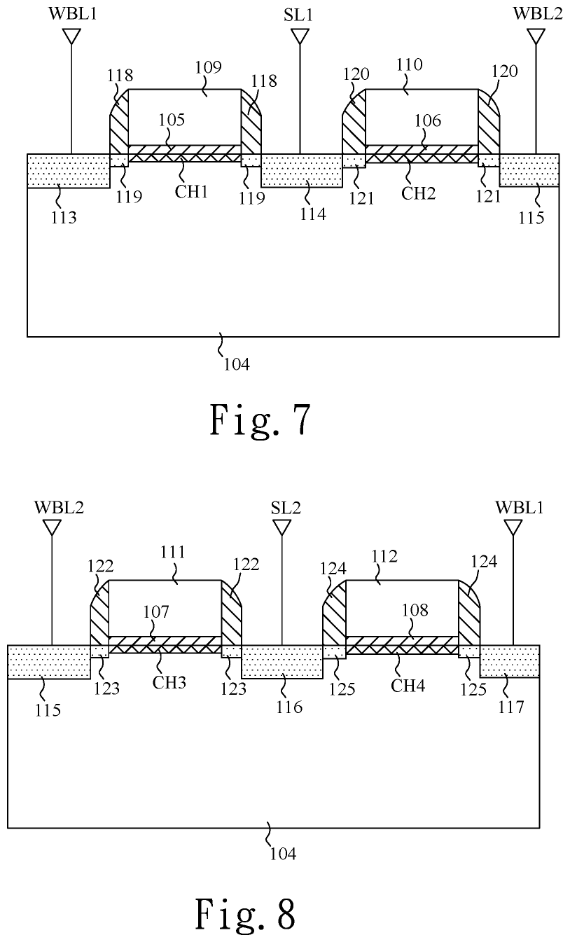

FIG. 7 is a cross-sectional view of a first memory cell and a second memory cell according to another embodiment of the present invention. FIG. 8 is a cross-sectional view of a third memory cell and a fourth memory cell according to another embodiment of the present invention. Referring to FIG. 7 and FIG. 8, the first memory cell 100, the second memory cell 101, the third memory cell 102, and the fourth memory cell 103 are formed in the semiconductor region 104 implemented with a semiconductor substrate. The other structures of the first memory cell 100, the second memory cell 101, the third memory cell 102, and the fourth memory cell 103 have been described previously so it will not be reiterated.

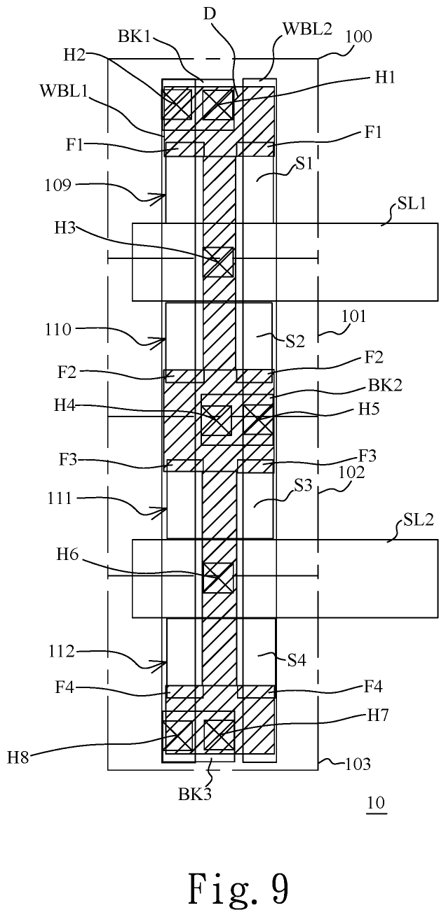

FIG. 9 is a schematic diagram illustrating the circuit layout of a sub-memory array according to another embodiment of the present invention. Please refer to FIG. 3, FIG. 4, and FIG. 9. Compared to the embodiment of FIG. 2, the first conductive gate 109 has a first strip portion S1 and first finger portions F1 vertical to the first strip portion S1. One end of each of the first finger portions F1 is connected to the first strip portion S1 and another end of each of the first finger portions F1 extends to the first heavily-doped area 113. The first finger portions F1 and the edge of the first gate dielectric block 105 generate a capacitance effect to increase capacitance. The second conductive gate 110 has a second strip portion S2 and second finger portions F2 vertical to the second strip portion S2. One end of each of the second finger portions F2 is connected to the second strip portion S2 and another end of each of the second finger portions F2 extends to the third heavily-doped area 115. The second finger portions F2 and the edge of the second gate dielectric block 106 generate a capacitance effect to increase capacitance. The third conductive gate 111 has a third strip portion S3 and third finger portions F3 vertical to the third strip portion S3. One end of each of the third finger portions F3 is connected to the third strip portion S3 and another end of each of the third finger portions F3 extends to the third heavily-doped area 115. The third finger portions F3 and the edge of the third gate dielectric block 107 generate a capacitance effect to increase capacitance. The fourth conductive gate 112 has a fourth strip portion S4 and fourth finger portions F4 vertical to the fourth strip portion S4. One end of each of the fourth finger portions F4 is connected to the fourth strip portion S4 and another end of each of the fourth finger portions F4 extends to the fifth heavily-doped area 117. The fourth finger portions F4 and the edge of the fourth gate dielectric block 108 generate a capacitance effect to increase capacitance.

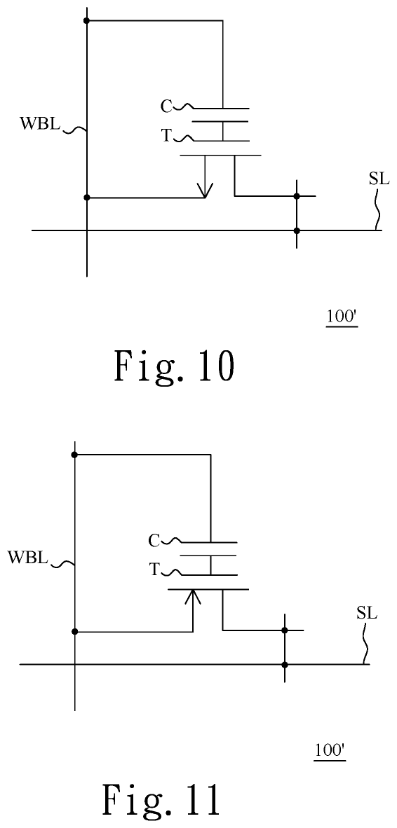

FIG. 10 is a schematic diagram illustrating the equivalent circuit of a read-only memory according to an embodiment of the present invention. FIG. 11 is a schematic diagram illustrating the equivalent circuit of a read-only memory according to another embodiment of the present invention. Please refer to FIG. 10 and FIG. 11. A read-only memory 100′ is introduced as follows. The read-only memory 100′ includes a field-effect transistor T and a capacitor C. The field-effect transistor T may be a P-channel metal-oxide-semiconductor field-effect transistor or an N-channel metal-oxide-semiconductor field-effect transistor. The source of the field-effect transistor T is coupled to a word bit line WBL and the drain of the field-effect transistor T is coupled to a common-source line SL. The word bit line WBL is perpendicular to the common-source line SL. One terminal of the capacitor C is coupled to the gate of the field-effect transistor T and another terminal of the capacitor C is coupled to the word bit line WBL.

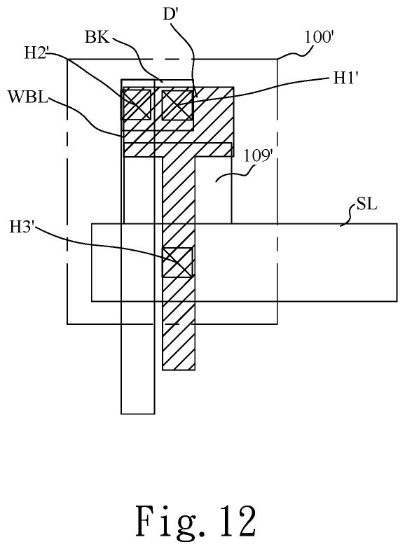

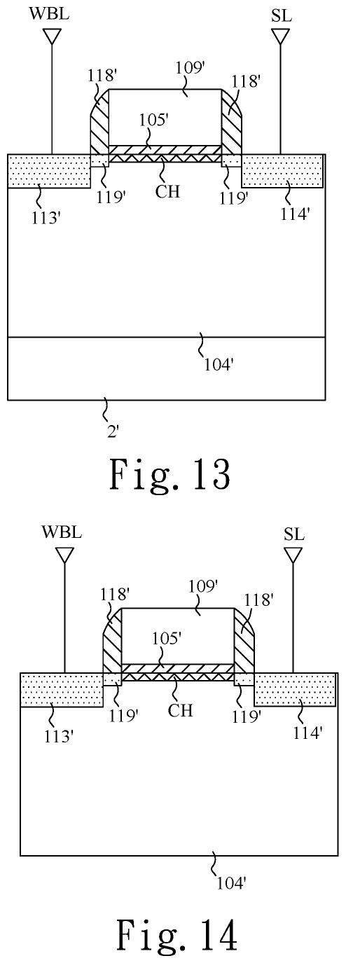

FIG. 12 is a schematic diagram illustrating the circuit layout of a read-only memory according to an embodiment of the present invention. FIG. 13 is a cross-sectional view of a read-only memory according to an embodiment of the present invention. Please refer to FIG. 12 and FIG. 13. The field-effect transistor T and the capacitor C are formed in a semiconductor region 104′ having a first conductivity type. The semiconductor region 104′ is a semiconductor substrate or an epitaxial layer formed on a semiconductor substrate. In the embodiment, the semiconductor region 104′ is an epitaxial layer formed on a semiconductor substrate 2′. The field-effect transistor T and the capacitor C commonly include a gate dielectric block 105′, a conductive gate 109′, a first heavily-doped area 113′, and a second heavily-doped area 114′. The gate dielectric block 105′ is a part of a dielectric layer D′. The conductive gate 109′ is a part of an electrode layer. The common-source line SL and a conduction block BK are a part of a first conduction metal layer. The word bit line WBL is a part of a second conduction metal layer. The gate dielectric block 105′ is formed on the semiconductor region 104′. The conductive gate 109′ is formed on the gate dielectric block 105′. The first heavily-doped area 113′ and the second heavily-doped area 114′ are formed in the semiconductor region 104′, respectively formed on two opposite side of the semiconductor region 104′, which is directly arranged under the conductive gate 109′, and respectively coupled to the word bit line WBL and the common-source line SL. The first heavily-doped area 113′ and the second heavily-doped area 114′ have a second conductivity type opposite to the first conductivity type. In an embodiment, the first conductivity type is a P type and the second conductivity type is an N type. In another embodiment, the first conductivity type is an N type and the second conductivity type is a P type. The electrode, the first conduction metal layer, and the second conduction metal layer are formed from bottom to top.

The word bit line WBL overlaps a second conduction via H2′. The second conduction via H2′ and a first conduction via H1′ overlap the conduction block BK. The first conduction via H1′ penetrates through the dielectric layer D′. The first heavily-doped area 113′ is coupled to the word bit line WBL through the first conduction via H1′, the conduction block BK, and the second conduction via H2′ in sequence. The common-source line SL overlaps a third conduction via H3′. The third conduction via H3′ penetrates through the dielectric layer D′. The second heavily-doped area 114′ is coupled to the common-source SL through the third conduction via H3′. Since the third conduction via H3′ only provides voltage for the common-source SL rather than connects to other components, the overall resistance of the read-only memory 100′ can be reduced.

The first heavily-doped area 113′, the second heavily-doped area 114′, the gate dielectric block 105′, the semiconductor region 104′, and the conductive gate 109′ form a metal-oxide-semiconductor field-effect transistor (MOSFET) T. The conductive gate 109′ and the first heavily-doped area 113′ form a capacitor C. The first heavily-doped area 113′ is used as a source and the second heavily-doped area 114′ is used as a drain. The two sidewalls of the conductive gate 109′ are respectively provided with two sidewall spacers 118′ that extend to the sidewall of the gate dielectric block 105′. There are two lightly-doped drains (LDDs) 119′ which are directly respectively formed under the two sidewall spacers 118′. When the MOSFET T is turned on, a channel region CH is formed between the LDDs 119′. The read-only memory employs the source of the field-effect transistor T to provide a gate voltage to greatly reduce the area of a capacitor.

FIG. 14 is a cross-sectional view of a read-only memory according to another embodiment of the present invention. Please refer to FIG. 14. The read-only memory 100′ may be formed in the semiconductor region 104′ implemented with a semiconductor substrate. The other structure of the read-only memory 100′ has been described previously so it will not be reiterated.

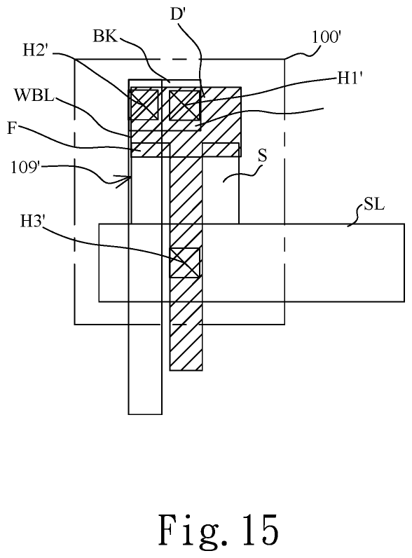

FIG. 15 is a schematic diagram illustrating the circuit layout of a read-only memory according to another embodiment of the present invention. Please refer to FIG. 13 and FIG. 15. The conductive gate 109′ has a strip portion S and finger portions F vertical to the strip portion S. One end of each of the finger portions F is connected to the strip portion S and another end of each of the finger portions F extends to the first heavily-doped area 113′. The finger portions F and the edge of the gate dielectric block 105′ generate a capacitance effect to increase capacitance.

According to the embodiments provided above, the multi-write read-only memory array employs the source of a field-effect transistor to provide a gate voltage to greatly reduce the area of a capacitor.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A multi-write read-only memory array comprising:
a plurality of common-source lines, arranged in parallel, comprising a first common-source line and a second common-source line;
a plurality of word bit lines arranged in parallel, wherein the plurality of word bit lines perpendicular to the plurality of common-source lines comprise a first word bit line and a second word bit line; and
a plurality of sub-memory arrays each coupled to two of the plurality of common-source lines and two of the plurality of word bit lines, wherein each of the plurality of sub-memory arrays comprises:
a first memory cell with a control terminal thereof coupled to the first word bit line and a data terminal of the first memory cell is coupled to the first common-source line and the first word bit line;
a second memory cell with a control terminal thereof coupled to the second word bit line and a data terminal of the second memory cell is coupled to the first common-source line and the second word bit line;
a third memory cell with a control terminal thereof coupled to the second word bit line and a data terminal of the third memory cell is coupled to the second common-source line and the second word bit line; and
a fourth memory cell with a control terminal thereof coupled to the first word bit line and a data terminal of the fourth memory cell is coupled to the second common-source line and the first word bit line.

2. The multi-write read-only memory array according to claim 1, wherein the first memory cell and the second memory cell are symmetric about the first common-source line, the third memory cell and the fourth memory cell are symmetric about the second common-source line, and the second memory cell and the third memory cell are located between the first memory cell and the fourth memory cell.

3. The multi-write read-only memory array according to claim 2, wherein the first memory cell, the second memory cell, the third memory cell, and the fourth memory cell are formed in a semiconductor region having a first conductivity type, and the first memory cell, the second memory cell, the third memory cell, and the fourth memory cell commonly comprise:
a first gate dielectric block, a second gate dielectric block, a third gate dielectric block, and a fourth gate dielectric block respectively formed on the semiconductor region;
a first conductive gate, a second conductive gate, a third conductive gate, and a fourth conductive gate respectively formed on the first gate dielectric block, the second gate dielectric block, the third gate dielectric block, and the fourth gate dielectric block;
a first heavily-doped area and a second heavily-doped area formed in the semiconductor region, respectively formed on two opposite side of the semiconductor region, which is directly arranged under the first conductive gate, and respectively coupled to the first word bit line and the first common-source line, wherein the first heavily-doped area and the second heavily-doped area have a second conductivity type opposite to the first conductivity type;
a third heavily-doped area formed in the semiconductor region, the second heavily-doped area and the third heavily-doped area are respectively formed on two opposite side of the semiconductor region, which is directly arranged under the second conductive gate, the third heavily-doped area is coupled to the second word bit line, and the third heavily-doped area has the second conductivity type;
a fourth heavily-doped area formed in the semiconductor region, the third heavily-doped area and the fourth heavily-doped area are respectively formed on two opposite side of the semiconductor region, which is directly arranged under the third conductive gate, the fourth heavily-doped area is coupled to the second common-source line, and the fourth heavily-doped area has the second conductivity type; and
a fifth heavily-doped area formed in the semiconductor region, the fourth heavily-doped area and the fifth heavily-doped area are respectively formed on two opposite side of the semiconductor region, which is directly arranged under the fourth conductive gate, the fifth heavily-doped area is coupled to the first word bit line, and the fifth heavily-doped area has the second conductivity type.

4. The multi-write read-only memory array according to claim 3, wherein the first conductivity type is a P type and the second conductivity type is an N type.

5. The multi-write read-only memory array according to claim 4, wherein when the first memory cell is selected to perform a programming activity, the semiconductor region is coupled to a grounding voltage, the first word bit line is coupled to a middle voltage or a high voltage, and the first common-source line is coupled to the grounding voltage or the middle voltage, wherein the high voltage is greater than the middle voltage and the middle voltage is greater than the grounding voltage.

6. The multi-write read-only memory array according to claim 4, wherein when the first memory cell is not selected to perform a programming activity, the semiconductor region is coupled to a grounding voltage, the first word bit line is coupled to the grounding voltage, and the first common-source line is coupled to a low voltage or electrically floating, wherein the low voltage is greater than the grounding voltage.

7. The multi-write read-only memory array according to claim 4, wherein when the first memory cell is selected to perform an erasing activity, the semiconductor region is coupled to a grounding voltage, the first word bit line is coupled to the grounding voltage, and the first common-source line is coupled to a high voltage, wherein the high voltage is greater than the grounding voltage.

8. The multi-write read-only memory array according to claim 4, wherein when the first memory cell is not selected to perform an erasing activity, the semiconductor region is coupled to a grounding voltage, the first word bit line is electrically floating or coupled to a low voltage, and the first common-source line is electrically floating, wherein the low voltage is greater than the grounding voltage.

9. The multi-write read-only memory array according to claim 4, wherein when the first memory cell is selected to perform a reading activity, the first word bit line is coupled to a low voltage and the semiconductor region and the first common-source line are coupled to a grounding voltage, wherein the low voltage is greater than the grounding voltage.

10. The multi-write read-only memory array according to claim 4, wherein when the first memory cell is not selected to perform a reading activity, the semiconductor region and the first word bit line are coupled to a grounding voltage and the first common-source line is coupled to a low voltage or electrically floating, wherein the low voltage is greater than the grounding voltage.

11. The multi-write read-only memory array according to claim 4, wherein when the second memory cell is selected to perform a programming activity, the semiconductor region is coupled to a grounding voltage, the second word bit line is coupled to a middle voltage or a high voltage, and the first common-source line is coupled to the grounding voltage or the middle voltage, wherein the high voltage is greater than the middle voltage and the middle voltage is greater than the grounding voltage.

12. The multi-write read-only memory array according to claim 4, wherein when the second memory cell is not selected to perform a programming activity, the semiconductor region is coupled to a grounding voltage, the second word bit line is coupled to the grounding voltage, and the first common-source line is coupled to a low voltage or electrically floating, wherein the low voltage is greater than the grounding voltage.

13. The multi-write read-only memory array according to claim 4, wherein when the second memory cell is selected to perform an erasing activity, the semiconductor region is coupled to a grounding voltage, the second word bit line is coupled to the grounding voltage, and the first common-source line is coupled to a high voltage, wherein the high voltage is greater than the grounding voltage.

14. The multi-write read-only memory array according to claim 4, wherein when the second memory cell is not selected to perform an erasing activity, the semiconductor region is coupled to a grounding voltage, the second word bit line is electrically floating or coupled to a low voltage, and the first common-source line is electrically floating, wherein the low voltage is greater than the grounding voltage.

15. The multi-write read-only memory array according to claim 4, wherein when the second memory cell is selected to perform a reading activity, the second word bit line are coupled to a low voltage and the semiconductor region and the first common-source line is coupled to a grounding voltage, wherein the low voltage is greater than the grounding voltage.

16. The multi-write read-only memory array according to claim 4, wherein when the second memory cell is not selected to perform a reading activity, the semiconductor region and the second word bit line are coupled to a grounding voltage and the first common-source line is coupled to a low voltage or electrically floating, wherein the low voltage is greater than the grounding voltage.

17. The multi-write read-only memory array according to claim 4, wherein when the third memory cell is selected to perform a programming activity, the semiconductor region is coupled to a grounding voltage, the second word bit line is coupled to a middle voltage or a high voltage, and the second common-source line is coupled to the grounding voltage or the middle voltage, wherein the high voltage is greater than the middle voltage and the middle voltage is greater than the grounding voltage.

18. The multi-write read-only memory array according to claim 4, wherein when the third memory cell is not selected to perform a programming activity, the semiconductor region is coupled to a grounding voltage, the second word bit line is coupled to the grounding voltage, and the second common-source line is coupled to a low voltage or electrically floating, wherein the low voltage is greater than the grounding voltage.

19. The multi-write read-only memory array according to claim 4, wherein when the third memory cell is selected to perform an erasing activity, the semiconductor region is coupled to a grounding voltage, the second word bit line is coupled to the grounding voltage, and the second common-source line is coupled to a high voltage, wherein the high voltage is greater than the grounding voltage.

20. The multi-write read-only memory array according to claim 4, wherein when the third memory cell is not selected to perform an erasing activity, the semiconductor region is coupled to a grounding voltage, the second word bit line is electrically floating or coupled to a low voltage, and the second common-source line is electrically floating, wherein the low voltage is greater than the grounding voltage.

21. The multi-write read-only memory array according to claim 4, wherein when the third memory cell is selected to perform a reading activity, the second word bit line are coupled to a low voltage and the semiconductor region and the second common-source line is coupled to a grounding voltage, wherein the low voltage is greater than the grounding voltage.

22. The multi-write read-only memory array according to claim 4, wherein when the third memory cell is not selected to perform a reading activity, the semiconductor region and the second word bit line are coupled to a grounding voltage and the second common-source line is coupled to a low voltage or electrically floating, wherein the low voltage is greater than the grounding voltage.

23. The multi-write read-only memory array according to claim 4, wherein when the fourth memory cell is selected to perform a programming activity, the semiconductor region is coupled to a grounding voltage, the first word bit line is coupled to a middle voltage or a high voltage, and the second common-source line is coupled to the grounding voltage or the middle voltage, wherein the high voltage is greater than the middle voltage and the middle voltage is greater than the grounding voltage.

24. The multi-write read-only memory array according to claim 4, wherein when the fourth memory cell is not selected to perform a programming activity, the semiconductor region is coupled to a grounding voltage, the first word bit line is coupled to the grounding voltage, and the second common-source line is coupled to a low voltage or electrically floating, wherein the low voltage is greater than the grounding voltage.

25. The multi-write read-only memory array according to claim 4, wherein when the fourth memory cell is selected to perform an erasing activity, the semiconductor region is coupled to a grounding voltage, the first word bit line is coupled to the grounding voltage, and the second common-source line is coupled to a high voltage, wherein the high voltage is greater than the grounding voltage.

26. The multi-write read-only memory array according to claim 4, wherein when the fourth memory cell is not selected to perform an erasing activity, the semiconductor region is coupled to a grounding voltage, the first word bit line is electrically floating or coupled to a low voltage, and the second common-source line is electrically floating, wherein the low voltage is greater than the grounding voltage.

27. The multi-write read-only memory array according to claim 4, wherein when the fourth memory cell is selected to perform a reading activity, the first word bit line are coupled to a low voltage and the semiconductor region and the second common-source line is coupled to a grounding voltage, wherein the low voltage is greater than the grounding voltage.

28. The multi-write read-only memory array according to claim 4, wherein when the fourth memory cell is not selected to perform a reading activity, the semiconductor region and the first word bit line are coupled to a grounding voltage and the second common-source line is coupled to a low voltage or electrically floating, wherein the low voltage is greater than the grounding voltage.

29. The multi-write read-only memory array according to claim 3, wherein the first conductivity type is an N type and the second conductivity type is a P type.

30. The multi-write read-only memory array according to claim 29, wherein when the first memory cell is selected to perform a programming activity, the semiconductor region is coupled to a high voltage, the first word bit line is coupled to a middle voltage or a grounding voltage, and the first common-source line is coupled to the middle voltage or the high voltage, wherein the high voltage is greater than the middle voltage and the middle voltage is greater than the grounding voltage.

31. The multi-write read-only memory array according to claim 29, wherein when the first memory cell is not selected to perform a programming activity, the semiconductor region is coupled to a high voltage, the first word bit line is coupled to the high voltage, and the first common-source line is coupled to a middle voltage or electrically floating, wherein the high voltage is greater than the middle voltage.

32. The multi-write read-only memory array according to claim 29, wherein when the first memory cell is selected to perform an erasing activity, the semiconductor region is coupled to a high voltage, the first word bit line is coupled to the high voltage, and the first common-source line is coupled to a grounding voltage, wherein the high voltage is greater than the grounding voltage.

33. The multi-write read-only memory array according to claim 29, wherein when the first memory cell is not selected to perform an erasing activity, the semiconductor region is coupled to a high voltage, the first word bit line is coupled to a middle voltage or electrically floating, and the first common-source line is electrically floating, wherein the high voltage is greater than the middle voltage.

34. The multi-write read-only memory array according to claim 29, wherein when the first memory cell is selected to perform a reading activity, the semiconductor region and the first common-source line are coupled to a middle voltage and the first word bit line is coupled to a low voltage, wherein the middle voltage is greater than the low voltage.

35. The multi-write read-only memory array according to claim 29, wherein when the first memory cell is not selected to perform a reading activity, the semiconductor region and the first word bit line are coupled to a middle voltage and the first common-source line is coupled to a low voltage or electrically floating, wherein the middle voltage is greater than the low voltage.

36. The multi-write read-only memory array according to claim 29, wherein when the second memory cell is selected to perform a programming activity, the semiconductor region is coupled to a high voltage, the second word bit line is coupled to a middle voltage or a grounding voltage, and the first common-source line is coupled to the middle voltage or the high voltage, wherein the high voltage is greater than the middle voltage and the middle voltage is greater than the grounding voltage.

37. The multi-write read-only memory array according to claim 29, wherein when the second memory cell is not selected to perform a programming activity, the semiconductor region is coupled to a high voltage, the second word bit line is coupled to the high voltage, and the first common-source line is coupled to a middle voltage or electrically floating, wherein the high voltage is greater than the middle voltage.

38. The multi-write read-only memory array according to claim 29, wherein when the second memory cell is selected to perform an erasing activity, the semiconductor region is coupled to a high voltage, the second word bit line is coupled to the high voltage, and the first common-source line is coupled to a grounding voltage, wherein the high voltage is greater than the grounding voltage.

39. The multi-write read-only memory array according to claim 29, wherein when the second memory cell is not selected to perform an erasing activity, the semiconductor region is coupled to a high voltage, the second word bit line is coupled to a middle voltage or electrically floating, and the first common-source line is electrically floating, wherein the high voltage is greater than the middle voltage.

40. The multi-write read-only memory array according to claim 29, wherein when the second memory cell is selected to perform a reading activity, the semiconductor region and the first common-source line are coupled to a middle voltage and the second word bit line is coupled to a low voltage, wherein the middle voltage is greater than the low voltage.

41. The multi-write read-only memory array according to claim 29, wherein when the second memory cell is not selected to perform a reading activity, the semiconductor region and the second word bit line are coupled to a middle voltage and the first common-source line is coupled to a low voltage or electrically floating, wherein the middle voltage is greater than the low voltage.

42. The multi-write read-only memory array according to claim 29, wherein when the third memory cell is selected to perform a programming activity, the semiconductor region is coupled to a high voltage, the second word bit line is coupled to a middle voltage or a grounding voltage, and the second common-source line is coupled to the middle voltage or the high voltage, wherein the high voltage is greater than the middle voltage and the middle voltage is greater than the grounding voltage.

43. The multi-write read-only memory array according to claim 29, wherein when the third memory cell is not selected to perform a programming activity, the semiconductor region is coupled to a high voltage, the second word bit line is coupled to the high voltage, and the second common-source line is coupled to a middle voltage or electrically floating, wherein the high voltage is greater than the middle voltage.

44. The multi-write read-only memory array according to claim 29, wherein when the third memory cell is selected to perform an erasing activity, the semiconductor region is coupled to a high voltage, the second word bit line is coupled to the high voltage, and the second common-source line is coupled to a grounding voltage, wherein the high voltage is greater than the grounding voltage.

45. The multi-write read-only memory array according to claim 29, wherein when the third memory cell is not selected to perform an erasing activity, the semiconductor region is coupled to a high voltage, the second word bit line is coupled to a middle voltage or electrically floating, and the second common-source line is electrically floating, wherein the high voltage is greater than the middle voltage.

46. The multi-write read-only memory array according to claim 29, wherein when the third memory cell is selected to perform a reading activity, the semiconductor region and the second common-source line are coupled to a middle voltage and the second word bit line is coupled to a low voltage, wherein the middle voltage is greater than the low voltage.

47. The multi-write read-only memory array according to claim 29, wherein when the third memory cell is not selected to perform a reading activity, the semiconductor region and the second word bit line are coupled to a middle voltage and the second common-source line is coupled to a low voltage or electrically floating, wherein the middle voltage is greater than the low voltage.

48. The multi-write read-only memory array according to claim 29, wherein when the fourth memory cell is selected to perform a programming activity, the semiconductor region is coupled to a high voltage, the first word bit line is coupled to a middle voltage or a grounding voltage, and the second common-source line is coupled to the middle voltage or the high voltage, wherein the high voltage is greater than the middle voltage and the middle voltage is greater than the grounding voltage.

49. The multi-write read-only memory array according to claim 29, wherein when the fourth memory cell is not selected to perform a programming activity, the semiconductor region is coupled to a high voltage, the first word bit line is coupled to the high voltage, and the second common-source line is coupled to a middle voltage or electrically floating, wherein the high voltage is greater than the middle voltage.

50. The multi-write read-only memory array according to claim 29, wherein when the fourth memory cell is selected to perform an erasing activity, the semiconductor region is coupled to a high voltage, the first word bit line is coupled to the high voltage, and the second common-source line is coupled to a grounding voltage, wherein the high voltage is greater than the grounding voltage.

51. The multi-write read-only memory array according to claim 29, wherein when the fourth memory cell is not selected to perform an erasing activity, the semiconductor region is coupled to a high voltage, the first word bit line is coupled to a middle voltage or electrically floating, and the second common-source line is electrically floating, wherein the high voltage is greater than the middle voltage.

52. The multi-write read-only memory array according to claim 29, wherein when the fourth memory cell is selected to perform a reading activity, the semiconductor region and the second common-source line are coupled to a middle voltage and the first word bit line is coupled to a low voltage, wherein the middle voltage is greater than the low voltage.

53. The multi-write read-only memory array according to claim 29, wherein when the fourth memory cell is not selected to perform a reading activity, the semiconductor region and the first word bit line are coupled to a middle voltage and the second common-source line is coupled to a low voltage or electrically floating, wherein the middle voltage is greater than the low voltage.

54. The multi-write read-only memory array according to claim 3, wherein the semiconductor region is a semiconductor substrate or an epitaxial layer formed on a semiconductor substrate.

55. The multi-write read-only memory array according to claim 3, wherein the first conductive gate has a first strip portion and first finger portions vertical to the first strip portion, one end of each of the first finger portions is connected to the first strip portion, another end of each of the first finger portions extends to the first heavily-doped area, the second conductive gate has a second strip portion and second finger portions vertical to the second strip portion, one end of each of the second finger portions is connected to the second strip portion, another end of each of the second finger portions extends to the third heavily-doped area, the third conductive gate has a third strip portion and third finger portions vertical to the third strip portion, one end of each of the third finger portions is connected to the third strip portion, another end of each of the third finger portions extends to the third heavily-doped area, the fourth conductive gate has a fourth strip portion and fourth finger portions vertical to the fourth strip portion, one end of each of the fourth finger portions is connected to the fourth strip portion, and another end of each of the fourth finger portions extends to the fifth heavily-doped area.

56. A read-only memory comprising:
a field-effect transistor with a source thereof coupled to a word bit line and a drain of the field-effect transistor is coupled to a common-source line, wherein the word bit line is perpendicular to the common-source line; and
a capacitor with one terminal thereof coupled to a gate of the field-effect transistor and another terminal of the capacitor is coupled to the word bit line.

57. The read-only memory according to claim 56, wherein the field-effect transistor and the capacitor are formed in a semiconductor region having a first conductivity type, and the field-effect transistor and the capacitor commonly comprise:
a gate dielectric block formed on the semiconductor region;
a conductive gate formed on the gate dielectric block; and
a first heavily-doped area and a second heavily-doped area formed in the semiconductor region, respectively formed on two opposite side of the semiconductor region, which is directly arranged under the conductive gate, and respectively coupled to the word bit line and the common-source line, wherein the first heavily-doped area and the second heavily-doped area have a second conductivity type opposite to the first conductivity type.

58. The read-only memory according to claim 57, wherein the first conductivity type is a P type and the second conductivity type is an N type.

59. The read-only memory according to claim 57, wherein the first conductivity type is an N type and the second conductivity type is a P type.

60. The read-only memory according to claim 57, wherein the conductive gate has a strip portion and finger portions vertical to the strip portion, one end of each of the finger portions is connected to the strip portion, and another end of each of the finger portions extends to the first heavily-doped area.

61. The read-only memory according to claim 57, wherein the semiconductor region is a semiconductor substrate or an epitaxial layer formed on a semiconductor substrate.
